(19) United States
(12) Patent Application Publication
(10) Pub. No.: US 2019/0393191 A1
(43) Pub. Date: Dec. 26, 2019

(54) PACKAGES OF STACKING INTEGRATED CIRCUITS

(71) Applicant: Intel IP Corporation, Santa Clara, CA (US)

(72) Inventors: Klaus REINGRUBER, Langquaid (DE); Georg SEIDEMANN, Landshut (DE); Andreas WOLTER, Regensburg (DE); Bernd WAIDHAS, Pettendorf (DE); Thomas WAGNER, Regelsbach (DE)

(21) Appl. No.: 16/464,213

(22) PCT Filed: Dec. 27, 2016
(86) PCT No.: PCT/US2016/068742

§ 371 Date: May 24, 2019

(51) Int. Cl. H01L 25/065; H01L 23/48; H01L 25/00; H01L 21/768

(52) U.S. Cl. CPC H01L 25/0652; H01L 23/481; H01L 2225/06541; H01L 21/76898; H01L 25/50

(57) ABSTRACT

Embodiments may include an IC having an active substrate containing devices, and a bulk substrate, separated by an oxide layer or an etching stop layer. The IC may be partially thinned from a backside of the bulk substrate to create a cavity, while maintaining the dicing streets and/or the edges of the bulk substrate without being thinned. The cavity may be surrounded by a first edge and a second edge of the bulk substrate. An additional IC may be placed within the cavity of the bulk substrate to form a stacking IC with a reduced height. The ICs of the stacking IC may be electronically coupled using TSVs embedded within the active substrate of the ICs. Other embodiments may be described and/or claimed.

### FIELD

Embodiments of the present disclosure relate generally to the technical field of electronic circuits, and more particularly to integrated circuit (IC) packages.

### BACKGROUND

An integrated circuit (IC) chip, often called a silicon chip, a computer chip, an IC, or a chip, may be a piece of silicon or another semiconductor into which an electronic circuit is etched using photographic techniques or other techniques. IC chips may be produced in batches on a wafer. A wafer may be cut (“diced”) into pieces along dicing streets. Each of these pieces may be called a die. An IC chip, e.g., a die or a wafer, may be assembled into a package. A package may be an interface between an IC chip and a printed circuit board (PCB). A packaged IC chip may be attached either to a PCB or to another substrate, to be coupled with other circuits to form an electronic system.

The semiconductor industry continues to improve the integration density of various electronic components (e.g., transistors, diodes, resistors, capacitors, etc.) by continual reductions in minimum feature size, which allow more components to be integrated into an area. These smaller electronic components may benefit from smaller packages that utilize less area than packages of the past. One form of smaller packages is thinner and slimmer packages to achieve slim form factors. One way to make slimmer packages is to make an IC chip thinner than IC chips in the past. A thin IC chip may be placed on a chip carrier to provide the physical support for the thin IC chip. Additional processing steps with additional cost may be performed to place a thin IC chip on a chip carrier. Therefore, chip carrier based packages for thin IC chips may be technically challenging, and it may be costly to achieve a desired slim form factors for IC chips. From further description herein, an IC chip may also be simply referred to as an IC.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates an IC including an active substrate and a bulk substrate having a cavity, in accordance with various embodiments.

FIG. 2 schematically illustrates another IC including an active substrate and a bulk substrate having a cavity, in accordance with various embodiments.

FIG. 3 schematically illustrates another IC including an active substrate and a bulk substrate having multiple cavities, in accordance with various embodiments.

FIG. 4 schematically illustrates a stacking IC having a first IC including an active substrate and a bulk substrate having a cavity, and a second IC placed within the cavity, in accordance with various embodiments.

FIG. 5 schematically illustrates another stacking IC having a first IC including an active substrate and a bulk substrate having a cavity, a second IC placed within the cavity of the first IC, and a third IC placed within a cavity of the second IC, in accordance with various embodiments.

FIG. 6 schematically illustrates a stacking IC having a first IC including an active substrate and a bulk substrate having two cavities, a second IC and a third IC placed within the cavities, in accordance with various embodiments.

FIG. 7 schematically illustrates a stacking IC having a first IC including an active substrate and a bulk substrate having a cavity, a second IC placed within the cavity, and a third IC packaged with the first IC and the second IC, in accordance with various embodiments.

FIG. 8 illustrates an example process for manufacturing an IC including an active substrate and a bulk substrate having a cavity, in accordance with various embodiments.

FIGS. 9(a)-9(l) illustrate another example process for manufacturing an IC including an active substrate and a bulk substrate having a cavity, in accordance with various embodiments.

FIG. 10 illustrates an example system configured to employ the apparatuses and methods described herein, in accordance with various embodiments.

### DETAILED DESCRIPTION

Embodiments herein may present techniques, systems, and apparatuses that achieve slim form factors for ICs without using a chip carrier and the additional processing associated with the chip carrier, hence reducing the cost. In embodiments, an IC, e.g., a die, or a wafer, may include an active substrate containing devices, and a bulk substrate, separated by an oxide layer or an etching stop layer. The IC may be partially thinned from a backside of the bulk substrate, without affecting the devices in the active substrate of the IC. The partial thinning of the IC may remove a part of the bulk substrate to create a cavity, while maintaining the dicing streets and/or the edges of the bulk substrate without being thinned. The edges on the bulk substrate may provide the stiffness and stability support in a way similar to a thicker die or wafer. An additional IC may be placed within the cavity of the bulk substrate to form a stacking IC with a reduced height. The ICs of the stacking IC may be electronically coupled using through silicon via (TSV) embedded within the active substrate of the ICs.

In various embodiments, a first IC may include an active substrate and a bulk substrate separated by an oxide layer placed on one side of the active substrate. The bulk substrate may include a cavity surrounded by a first edge of the bulk substrate and a second edge of the bulk substrate. In some embodiments, the cavity of the bulk substrate may be completely through the bulk substrate to expose the oxide layer, and surrounded by the first edge of the bulk substrate, the second edge of the bulk substrate, and the oxide layer. Furthermore, a second IC may be placed within the cavity of the bulk substrate of the first IC. The first IC and the second IC may be electronically coupled using TSVs embedded within the active substrate of the first IC. In embodiments, the TSV may be formed through the active substrate, exposed in the cavity of the bulk substrate. Furthermore, the TSV may be separated from the active substrate by a vertical oxide layer through the active substrate.

In various embodiments, the second IC placed within the cavity of the bulk substrate of the first IC may similarly include: a second active substrate and a second bulk substrate separated by a second oxide layer. In addition, the second bulk substrate may include a cavity surrounded by a first edge of the second bulk substrate and a second edge of the second bulk substrate. A third IC may be placed within the cavity of the second bulk substrate. The third IC and the second IC may be electronically coupled using more TSVs, where the more TSVs may be exposed in the cavity of the second bulk substrate.

In various embodiments, an electronic system may include a PCB and a stacking IC affixed to the PCB. In more detail, the stacking IC may include a first IC having a cavity formed on a bulk substrate, and a second IC placed within the cavity of the bulk substrate, electronically coupled to the first IC using TSVs. The first IC may also include an active substrate containing a device, and separated from the bulk substrate by an oxide layer. The TSVs may be through the active substrate of the first IC and separated from the active substrate by a vertical oxide layer.

In various embodiments, a method for making a stacking IC may include: providing an IC, wherein the IC may include an active substrate, a bulk substrate, and a first oxide layer between the active substrate and the bulk substrate; forming an opening through the active substrate, the first oxide layer, and partially into the bulk substrate; forming a second oxide layer conformal to a surface of the active substrate, and around walls of the opening; forming a through silicon via (TSV) next to the second oxide layer in the opening to fill the opening; and forming a cavity of the bulk substrate by removing a part of the bulk substrate, wherein the TSV is exposed in the cavity of the bulk substrate, and wherein the cavity of the bulk substrate is surrounded by a first edge of the bulk substrate and a second edge of the bulk substrate. Furthermore, another IC may be placed within the cavity of the bulk substrate to form the stacking IC.

In the following detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, side, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

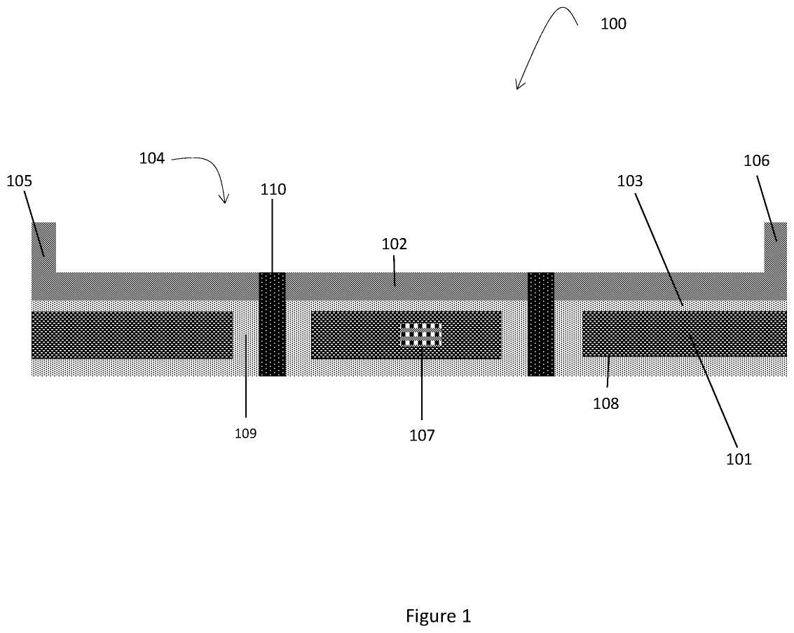

FIG. 1 schematically illustrates an IC 100 including an active substrate 101 and a bulk substrate 102 having a cavity 104, in accordance with various embodiments. In more detail, the cavity 104 may be surrounded by a first edge 105 and a second edge 106 of the bulk substrate 102. The active substrate 101 may include a device 107. An oxide layer 103 may be on one side of the active substrate 101, separating the active substrate 101 and the bulk substrate 102. A TSV 110 may be through the active substrate 101, wherein the TSV 110 may be exposed in the cavity 104 of the bulk substrate 102. The TSV 110 may be separated from the active substrate 101 by a vertical oxide layer 109 through the active substrate 101, and the vertical oxide layer 109 may be in contact with the oxide layer 103. In addition, the active substrate 101 may be covered by an oxide layer 108 at a side opposite to the oxide layer 103. The oxide layer 108 may be in contact with the vertical oxide layer 109 as well.

In embodiments, the IC 100 may be a die or a wafer. The active substrate 101 or the bulk substrate 102 may include a polymeric substrate, a non-polymeric substrate, a silicon substrate, a silicon on insulator (SOI) substrate, or a silicon on sapphire (SOS) substrate. Generally, an SOI substrate may include a layer of a semiconductor material such as silicon, germanium, silicon germanium, silicon germanium on insulator (SGOI), or combinations thereof. The active substrate 101 or the bulk substrate 102 may include a multi-layered substrate, a gradient substrate, or a hybrid orientation substrate. The active substrate 101 may include the device 107, which may be an active device such as a transistor, or a passive device such as a resistor or a capacitor. The active substrate 101 may also include shallow trench isolation (STI) regions, and other passive devices, not shown for simplicity reasons.

The oxide layer 103, the vertical oxide layer 109, and/or the oxide layer 108 may include a silicon dioxide (SiO₂), or a silicon oxide. Other materials may be used too for the oxide layer 103, such as a silicon carbide (SiC), or a silicon nitride (SiN). The oxide layer 103 may function as an etching stop layer between the active substrate 101 and the bulk substrate 102. When the cavity 104 of the bulk substrate 102 is formed, the etching stop layer, e.g., the oxide layer 103, may prevent the active substrate 101 and devices contained within the active substrate 101 from being affected by the process of forming the cavity 104.

In embodiments, the TSV 110 may be a part of an interconnect structure of the IC 100. The TSV 110 may include aluminum (Al), copper (Cu), tin (Sn), nickel (Ni), gold (Au), silver (Ag), tungsten (W), polysilicon, doped silicon, or other electrically conductive material. The interconnect structure of the IC 100 may further include bumps or pillars, not shown for simplicity reasons. The interconnect structure, including the TSV 110, may be configured to route electrical signals between ICs or between ICs and package substrates, or PCB. In some embodiments, the interconnect structures may be configured to route electrical signals such as, for example, input/output (I/O) signals and/or power or ground signals associated with the operation of the IC 100.

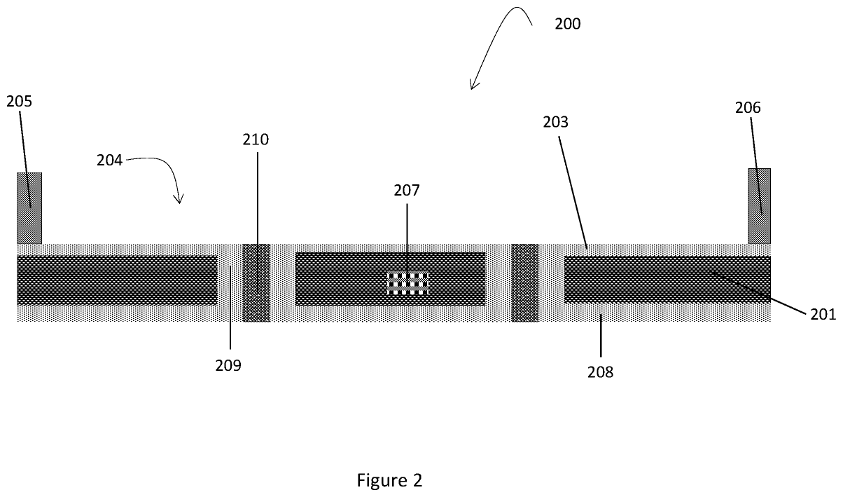

In embodiments, the cavity 104 may be formed of different sizes and shapes. For example, as shown in FIG. 1, the cavity 104 may be surrounded by the first edge 105 and the second edge 106 at two sides, with the bulk substrate 102 at the bottom of the cavity 104. In some other embodiments, the cavity 104 may be surrounded by the first edge 105 and the second edge 106 at two sides, while the bulk substrate 102 may be completely removed at the bottom of the cavity 104, as shown in FIG. 2. The sizes and the shapes of the cavity 104 may be determined by the IC placed within the cavity 104.

FIG. 2 schematically illustrates another IC, e.g., an IC 200, including an active substrate 201 and a bulk substrate having a cavity 204, in accordance with various embodiments. In embodiments, the IC 200 may be similar to the IC 100, while the cavity 204 may be similar to the cavity 104 in FIG. 1. The detailed description for each part of the IC 200 may be similar to the description of a similar part for the IC 100.

In more detail, the cavity 204 may be surrounded by a first edge 205 and a second edge 206, where the first edge 205 and the second edge 206 may be a part of a bulk substrate. Different from the cavity 104 shown in FIG. 1, the cavity 204 may be formed on the bulk substrate so that the cavity 204 is completely through the bulk substrate to expose an oxide layer 203. After the cavity 204 is formed, the bulk substrate may have the first edge 205 and the second edge 206 remaining, and the rest of the bulk substrate is removed. As a result, the cavity 204 may be surrounded by the first edge 205 of the bulk substrate, the second edge 206 of the bulk substrate, and the oxide layer 203.

In embodiments, the active substrate 201 may include a device 207. The oxide layer 203 may be on one side of the active substrate 201, separating the active substrate 201 and the bulk substrate. The oxide layer 203 may function as an etching stop layer between the active substrate 201 and the bulk substrate. When the cavity 204 of the bulk substrate is formed, the etching stop layer, e.g., the oxide layer 203, may prevent the active substrate 201 and devices contained within the active substrate 201 from being affected by the process of forming the cavity 204. In addition, the active substrate 201 may be covered by an oxide layer 208 at a side opposite to the oxide layer 203.

In embodiments, a TSV 210 may be through the active substrate 201, wherein the TSV 210 may be exposed in the cavity 204. The TSV 210 may be separated from the active substrate 201 by a vertical oxide layer 209 through the active substrate 201, and the vertical oxide layer 209 may be in contact with the oxide layer 203 and the oxide layer 208. The TSV 210 may be a part of an interconnect structure of the IC 200. The TSV 210 may include aluminum (Al), copper (Cu), tin (Sn), nickel (Ni), gold (Au), silver (Ag), tungsten (W), polysilicon, doped silicon, or other electrically conductive material. The interconnect structure of the IC 200 may further include bumps or pillars, not shown for simplicity reasons. The interconnect structure, including the TSV 210, may be configured to route electrical signals between ICs or between ICs and package substrates, or PCB. In some embodiments, the interconnect structures may be configured to route electrical signals such as, for example, input/output (I/O) signals and/or power or ground signals associated with the operation of the IC 200.

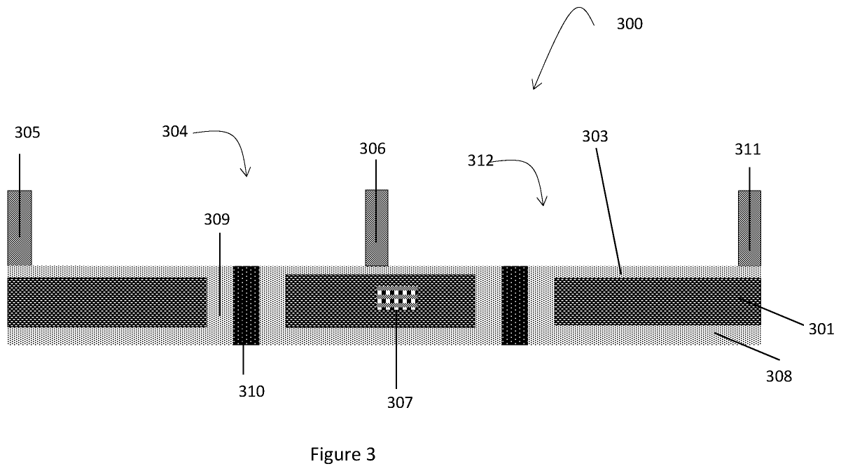

FIG. 3 schematically illustrates another IC, e.g., an IC 300, including an active substrate 301 and a bulk substrate having multiple cavities, in accordance with various embodiments. In embodiments, the IC 300 may be similar to the IC 100, while a first cavity 304 may be similar to the cavity 104 in FIG. 1. In addition, the IC 300 may have a second cavity 312. The detailed description for each part of the IC 300 may be similar to the description of a similar part for the IC 100.

In more detail, similar to IC 100, the first cavity 304 may be surrounded by a first edge 305 and a second edge 306, where the first edge 305 and the second edge 306 may be a part of a bulk substrate. In embodiments, the IC 300 may be a wafer, and the second edge 306 may be formed along a dicing street of the wafer. In addition, the second cavity 312 may be formed by the second edge 306 and a third edge 311, where the third edge 311 may be an edge of the wafer, or along a dicing street of the wafer. More cavities may be formed on the bulk substrate surrounded by edges along dicing streets of the wafer, or edges of the wafer. The first cavity 304 and the second cavity 312 may be formed partially through the bulk substrate, or completely through the bulk substrate. In some embodiments, one cavity may be formed partially through the bulk substrate, while another cavity may be formed completely through the bulk substrate.

In embodiments, the active substrate 301 may include a device 307. An oxide layer 303 may be on one side of the active substrate 301, separating the active substrate 301 and the bulk substrate. The oxide layer 303 may function as an etching stop layer between the active substrate 301 and the bulk substrate. When the first cavity 304 and/or the second cavity 312 of the bulk substrate are formed, the etching stop layer, e.g., the oxide layer 303, may prevent the active substrate 301 and devices, e.g., the device 307, contained within the active substrate 301 from being affected by the process of forming the first cavity 304 and/or the second cavity 312. In addition, the active substrate 301 may be covered by an oxide layer 308 at a side opposite to the oxide layer 303.

In embodiments, a TSV 310 may be through the active substrate 301, wherein the TSV 310 may be exposed in the first cavity 304 or the second cavity 312. The TSV 310 may be separated from the active substrate 301 by a vertical oxide layer 309 through the active substrate 301, and the vertical oxide layer 309 may be in contact with the oxide layer 303 and the oxide layer 308. The TSV 310 may be a part of an interconnect structure of the IC 300. The TSV 310 may include aluminum (Al), copper (Cu), tin (Sn), nickel (Ni), gold (Au), silver (Ag), tungsten (W), polysilicon, doped silicon, or other electrically conductive material. The interconnect structure of the IC 300 may further include bumps or pillars, not shown for simplicity reasons. The interconnect structure, including the TSV 310, may be configured to route electrical signals between ICs or between ICs and package substrates, or PCB. In some embodiments, the interconnect structures may be configured to route electrical signals such as, for example, input/output (I/O) signals and/or power or ground signals associated with the operation of the IC 300.

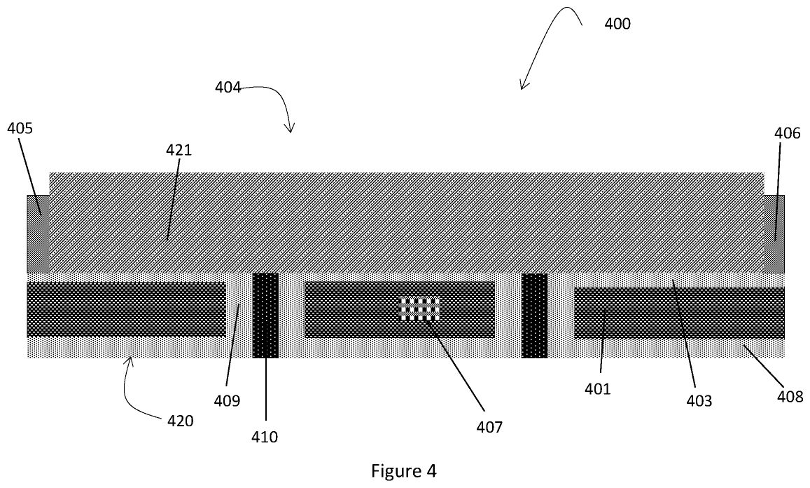

FIG. 4 schematically illustrates a stacking IC 400, having a first IC 420 including an active substrate 401 and a bulk substrate having a cavity 404, and a second IC 421 placed within the cavity 404, in accordance with various embodiments. In embodiments, the first IC 420 may be similar to the IC 100 or the IC 200, while the cavity 404 may be similar to the cavity 104 in FIG. 1 or the cavity 204 in FIG. 2. The detailed description for each part of the first IC 420 may be similar to the description of a similar part for the IC 100 or a similar part for the IC 200.

In more detail, the first IC 420 may include the active substrate 401. The active substrate 401 may include a device 407. The cavity 404 may be formed in a bulk substrate, surrounded by a first edge 405 and a second edge 406 of the bulk substrate. An oxide layer 403 may be on one side of the active substrate 401, separating the active substrate 401 and the bulk substrate. A TSV 410 may be through the active substrate 401, wherein the TSV 410 may be exposed in the cavity 404 of the bulk substrate. The TSV 410 may be separated from the active substrate 401 by a vertical oxide layer 409 through the active substrate 401, and the vertical oxide layer 409 may be in contact with the oxide layer 403. In addition, the active substrate 401 may be covered by an oxide layer 408 at a side opposite to the oxide layer 403. The oxide layer 408 may be in contact with the vertical oxide layer 409 as well.

In some embodiments, the cavity 404 may be surrounded by the first edge 405 and the second edge 406 at two sides, while the bulk substrate may be completely removed at the bottom of the cavity 404, as shown in FIG. 4. Alternatively, in some other embodiments, the cavity 404 may be similar to the cavity 104 of FIG. 1, with a part of the bulk substrate at the bottom of the cavity 404. The first edge 405 and the second edge 406 may provide the stiffness and stability support for the stacking IC 400, in a way similar to a thicker die or wafer.

The second IC 421 may be placed within the cavity 404 of the first IC 420. The second IC 421 may include a die, and a connector connected to the TSV 410 of the first IC 420. By placing the second IC 421 within the cavity 404 of the first IC 420, the total height of the stacking IC 400 including the first IC 420 and the second IC 421 may be lower than simply bonding the first IC 420 and the second IC 421 together without any cavity in the first IC 420.

The sizes and the shapes of the cavity 404 may be determined by the second IC 421 placed within the cavity 404. The size of the cavity 404 may be large compared to the size, e.g., the width or the height, of the second IC 421, so that there may be a gap between the second IC 421 and the first edge 405 and/or the second edge 406. In some other embodiments, the size of the cavity 404 may be comparable to the size of the second IC 421, so that a gap between the second IC 421 and the first edge 405 and/or the second edge 406 may be negligible.

The first IC 420 and the second IC 421 placed within a cavity of the first IC 420 may form the stacking IC 400, coupled vertically using TSVs, e.g., the TSV 410, so that they behave as a single device to achieve performance improvements at reduced power and smaller footprint than simply adding one IC over another IC without a cavity. In addition, there may be a solder ball or copper pillar placed at the second IC 421 before the second IC 421 is placed within the cavity 404, to make the vertical connection between the first IC 420 and the second IC 421. In embodiments, the first IC 420 and/or the second IC 421 may be a die or a wafer. Therefore, the stacking IC 400 may be a die-to-die stacking IC, a die-to-wafer stacking IC, or a wafer-to-wafer stacking IC. In embodiments, the first IC 420 and the second IC 421 may be formed on a wafer, and then singulated along the dicing streets of the wafer to form individual dies. One advantage of the die-to-die stacking IC 400 may be that each component die, e.g., the first IC 420 or the second IC 421, may be tested first, so that one bad die does not ruin an entire stack.

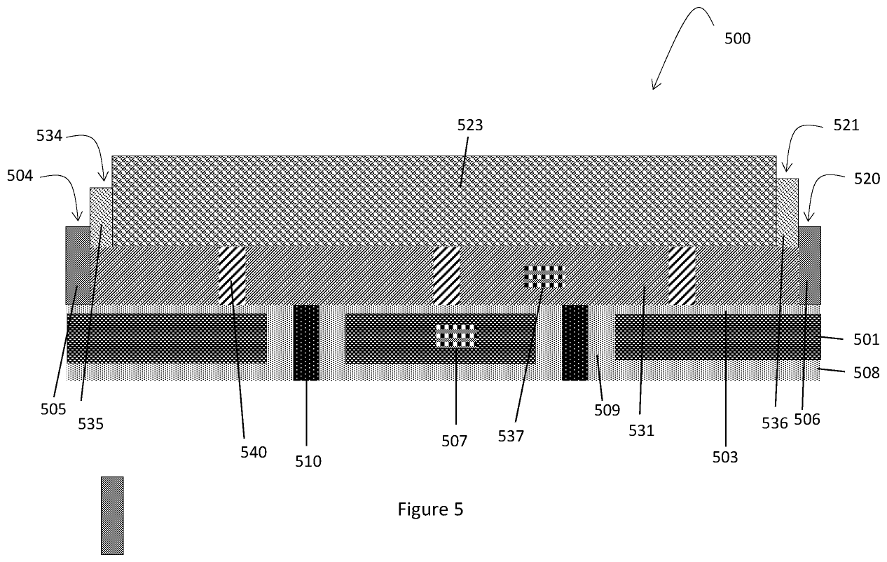

FIG. 5 schematically illustrates another stacking IC 500, having a first IC 520 including an active substrate 501 and a bulk substrate having a cavity 504, a second IC 521 placed within the cavity 504 of the first IC 520, and a third IC 523 placed with a cavity 534 of the second IC 521, in accordance with various embodiments.

In embodiments, the first IC 520 may be similar to the IC 100 or the IC 200, while the cavity 504 may be similar to the cavity 104 in FIG. 1 or the cavity 204 in FIG. 2. The detailed description for each part of the first IC 520 may be similar to the description of a similar part for the IC 100 or a similar part for the IC 200. Furthermore, the second IC 521 may also be similar to the IC 100 or the IC 200. The second IC 521 may further include the cavity 534, which may be similar to the cavity 104 or the cavity 204. In some embodiments, the third IC 523 may be similar to the IC 100 with a cavity. Alternatively, the third IC 523 may be an IC without a cavity on the substrate.

In more detail, the first IC 520 may include the active substrate 501. The active substrate 501 may include a device 507. The cavity 504 may be formed in a bulk substrate, surrounded by a first edge 505 and a second edge 506 of the bulk substrate. An oxide layer 503 may be on one side of the active substrate 501, separating the active substrate 501 and the bulk substrate. A TSV 510 may be through the active substrate 501, wherein the TSV 510 may be exposed in the cavity 504 of the bulk substrate. The TSV 510 may be separated from the active substrate 501 by a vertical oxide layer 509 through the active substrate 501, and the vertical oxide layer 509 may be in contact with the oxide layer 503. In addition, the active substrate 501 may be covered by an oxide layer 508 at a side opposite to the oxide layer 503. The oxide layer 508 may be in contact with the vertical oxide layer 509 as well.

The second IC 521 may be placed within the cavity 504 of the first IC 520. The second IC 521 may include a die, and a connector connected to the TSV 510 of the first IC 520. In embodiments, the second IC 521 may include an active substrate 531, containing a device 537. The second IC 521 may further include the cavity 534 formed in a bulk substrate, surrounded by a first edge 535 and a second edge 536 of the bulk substrate of the second IC 521. In some embodiments, the cavity 534 may be formed after the second IC 521 being placed within the cavity 504 of the first IC 520. A TSV 540 may be through the active substrate 531, wherein the TSV 540 may be exposed in the cavity 534. Furthermore, the second IC 521 may include various oxide layers or etch stop layers, not shown for simplicity reasons. The third IC 523 may be placed within the cavity 534 of the second IC 521.

The first IC 520, the second IC 521, and the third IC 523 may form the stacking IC 500, coupled vertically using TSVs, e.g., the TSV 510 and TSV 540, so that they behave as a single device to achieve performance improvements at reduced power and smaller footprint than simply stacking ICs together without cavities. In embodiments, the first IC 520, the second IC 521, and/or the third IC 523 may be a die or a wafer. Therefore, the stacking IC 500 may be a die-to-die stacking IC, a die-to-wafer stacking IC, or a wafer-to-wafer stacking IC.

In embodiments, there may be more than three ICs coupled together in a way similarly as shown in FIG. 5. For example, there may be four or more ICs coupled together, using similar techniques as shown in FIG. 5.

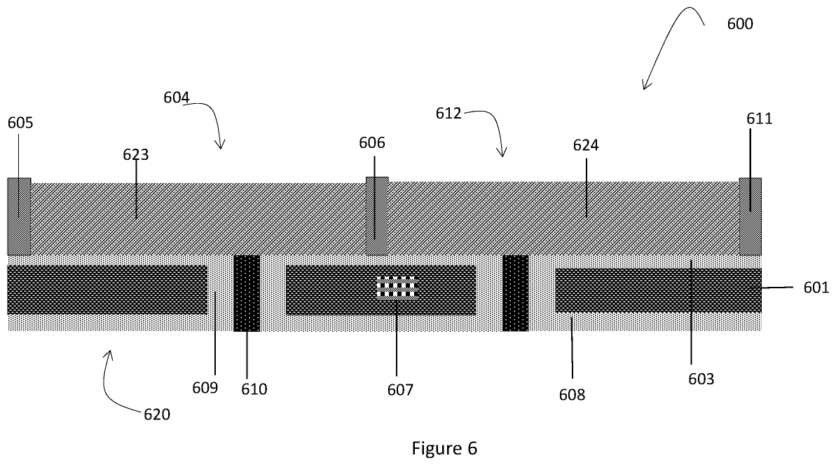

FIG. 6 schematically illustrates a stacking IC 600 having a first IC 620 including an active substrate 601 and a bulk substrate having two cavities, a second IC 623 and a third IC 624 placed within the cavities, in accordance with various embodiments.

In embodiment, the first IC 620 may be similar to the IC 300, while the cavity 604 may be similar to the cavity 304, and the cavity 612 may be similar to the cavity 312 in FIG. 3. The detailed description for each part of the first IC 620 may be similar to the description of a similar part for the IC 300.

In more details, the first IC 620 may include the active substrate 601. The active substrate 601 may include a device 607. An oxide layer 603 may be on one side of the active substrate 601, separating the active substrate 601 and the bulk substrate. A TSV 610 may be through the active substrate 601. The TSV 610 may be separated from the active substrate 601 by a vertical oxide layer 609 through the active substrate 601, and the vertical oxide layer 609 may be in contact with the oxide layer 603. In addition, the active substrate 601 may be covered by an oxide layer 608 at a side opposite to the oxide layer 603. The oxide layer 608 may be in contact with the vertical oxide layer 609 as well.

The cavity 604 may be formed in a bulk substrate, surrounded by a first edge 605 and a second edge 606, where the first edge 605 and the second edge 606 may be a part of the bulk substrate. In embodiments, the first IC 620 may be a wafer, and the second edge 606 may be formed along a dicing street of the wafer. In addition, the second cavity 612 may be formed by the second edge 606 and a third edge 611, where the third edge 611 may be an edge of the wafer, or along a dicing street of the wafer. More cavities may be formed on the bulk substrate surrounded by edges along dicing streets of the wafer, or edges of the wafer. The cavity 604 and the cavity 612 may be formed partially through the bulk substrate, or completely through the bulk substrate. The TSV 610 may be exposed in the cavity 604 and/or the cavity 612.

The second IC 623 may be placed within the cavity 604 of the bulk substrate. The second IC 623 may include a die, and a connector connected to the TSV 610 of the first IC 620. Similarly, the third IC 624 may be placed within the cavity 612 of the bulk substrate. The third IC 624 may include a die, and a connector connected to the TSV 610 of the first IC 620. In embodiments, the second IC 623 and the third IC 624 may include an active substrate containing devices and TSVs. The second IC 623 and the third IC 624 may further include a cavity formed in a bulk substrate.

The first IC 620, the second IC 623, and the third IC 624 may form the stacking IC 600, coupled vertically using TSVs, e.g., the TSV 610, so that they behave as a single device to achieve performance improvements at reduced power and smaller footprint. In embodiments, the first IC 620 may be a wafer, while the second IC 623 and/or the third IC 624 may be a die or a wafer of a different size. Therefore, the stacking IC 600 may be a wafer-to-die stacking IC, or a wafer-to-wafer stacking IC.

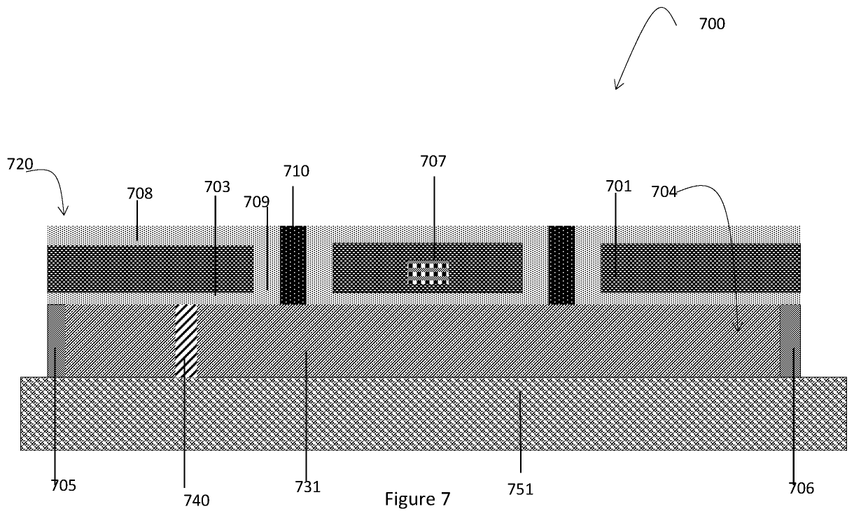

FIG. 7 schematically illustrates a stacking IC 700 having a first IC 720 including an active substrate 701 and a bulk substrate having a cavity 704, a second IC 731 placed within the cavity 704, and a third IC 751 packaged with the first IC 720 and the second IC 731, in accordance with various embodiments.

In embodiments, the first IC 720 may be similar to the IC 100 or the IC 200, while the cavity 704 may be similar to the cavity 104 in FIG. 1 or the cavity 204 in FIG. 2. The detailed description for each part of the first IC 720 may be similar to the description of a similar part for the IC 100 or a similar part for the IC 200.

In more detail, the first IC 720 may include the active substrate 701. The active substrate 701 may include a device 707. An oxide layer 703 may be on one side of the active substrate 701, separating the active substrate 701 and the bulk substrate. A TSV 710 may be through the active substrate 701. The TSV 710 may be separated from the active substrate 701 by a vertical oxide layer 709 through the active substrate 701, and the vertical oxide layer 709 may be in contact with the oxide layer 703. In addition, the active substrate 701 may be covered by an oxide layer 708 at a side opposite to the oxide layer 703. The oxide layer 708 may be in contact with the vertical oxide layer 709 as well.

The cavity 704 may be formed in a bulk substrate, surrounded by a first edge 705 and a second edge 706, where the first edge 705 and the second edge 706 may be a part of the bulk substrate. In embodiments, the first IC 720 may be a wafer or a die. The cavity 704 may be formed partially through the bulk substrate, or completely through the bulk substrate. The TSV 710 may be exposed in the cavity 704.

The second IC 731 may be placed within the cavity 704 of the first IC 720. The second IC 731 may include a die, a connector, and a TSV 740, which may be connected to the TSV 710 of the first IC 720. The second IC 731 may be an IC without a cavity. Alternatively, the second IC 731 may be an IC with a cavity.

The first IC 720 and the second IC 731 may be packaged together with the third IC 751 to form the stacking IC 700. The first IC 720, the second IC 731, and the third IC 751 may be coupled vertically using TSVs, e.g., the TSV 710, so that they behave as a single device to achieve performance improvements at reduced power and smaller footprint. In embodiments, the first IC 720 may be a wafer, while the second IC 731 and the third IC 751 may be a die or a wafer of a different size. The stacking IC 700 may be placed on a substrate or a PCB.

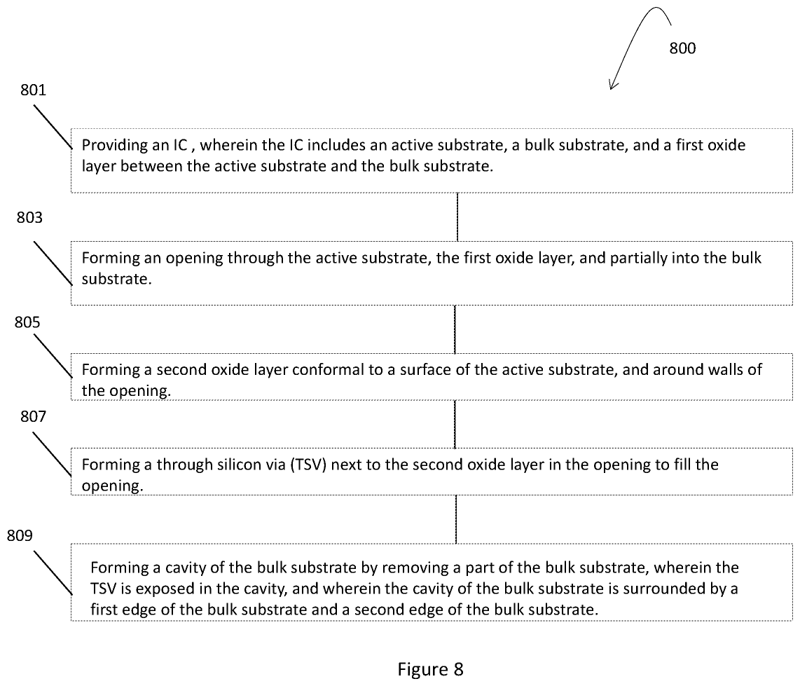

FIG. 8 illustrates an example process 800 for manufacturing an IC including an active substrate and a bulk substrate having a cavity, in accordance with various embodiments. In embodiments, various processes may be used to manufacture an IC, e.g., the IC 100 of FIG. 1, the IC 200 of FIG. 2, or the IC 300 of FIG. 3.

Operation 801 may be performed to provide an IC, wherein the IC may include an active substrate, a bulk substrate, and a first oxide layer between the active substrate and the bulk substrate. For example, as shown in FIG. 1, an IC, e.g., the IC 100, may be provided, where the IC 100 may include the active substrate 101 and the bulk substrate 102 separated by the oxide layer 103.

Operation 803 may be performed to form an opening through the active substrate, the first oxide layer, and partially into the bulk substrate. For example, as shown in FIG. 1, an opening may be formed through the active substrate 101, the oxide layer 103, and partially into the bulk substrate 102, where the opening may be used to house the TSV 110.

Operation 805 may be performed to form a second oxide layer conformal to a surface of the active substrate, and around walls of the opening. For example, as shown in FIG. 1, the oxide layer 108 and the vertical oxide layer 109 may be formed conformal to a surface of the active substrate, and around walls of the opening.

Operation 807 may be performed to form a TSV next to the second oxide layer in the opening to fill the opening. For example, as shown in FIG. 1, the TSV 110 may be formed next to the vertical oxide layer 109 in the opening to fill the opening.

Operation 809 may be performed to form a cavity of the bulk substrate by removing a part of the bulk substrate, wherein the TSV is exposed in the cavity of the bulk substrate, and wherein the cavity of the bulk substrate is surrounded by a first edge of the bulk substrate and a second edge the bulk substrate. For example, as shown in FIG. 1, the cavity 104 may be formed on the bulk substrate 102, and surrounded by the first edge 105 and the second edge 106. The TSV 110 may be exposed in the cavity 104.

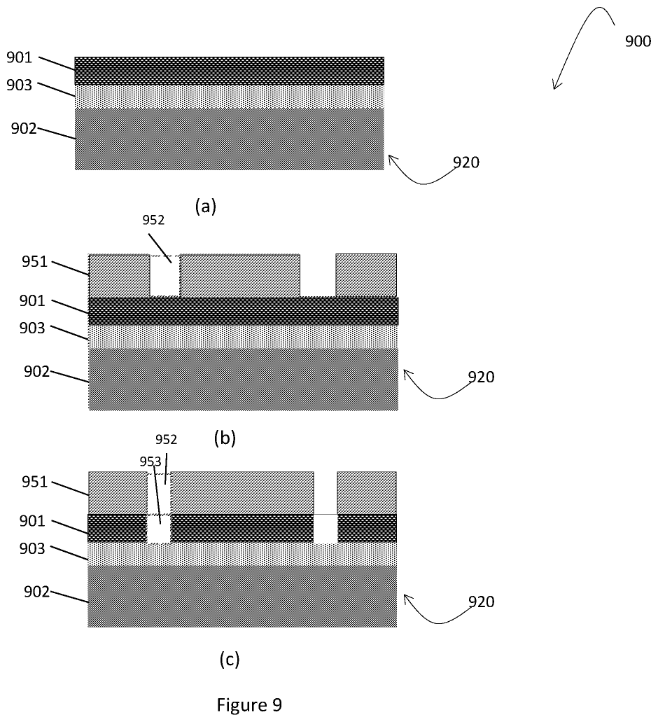

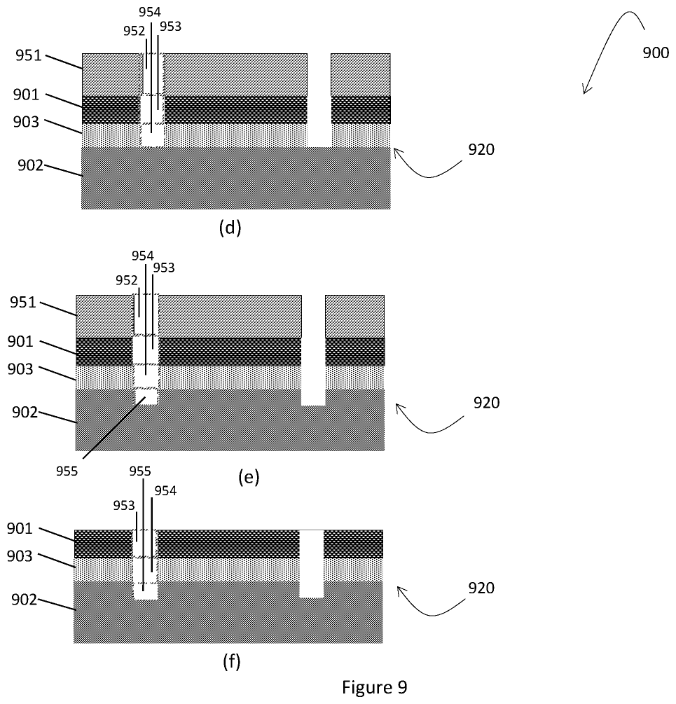

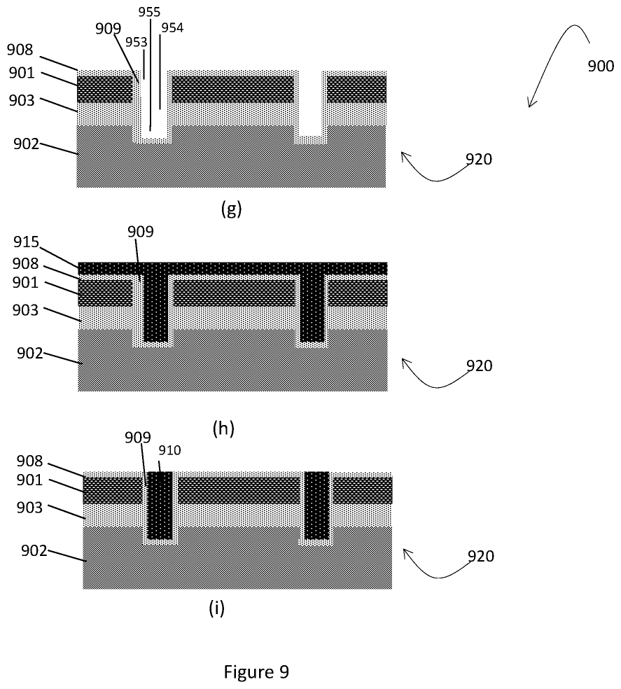

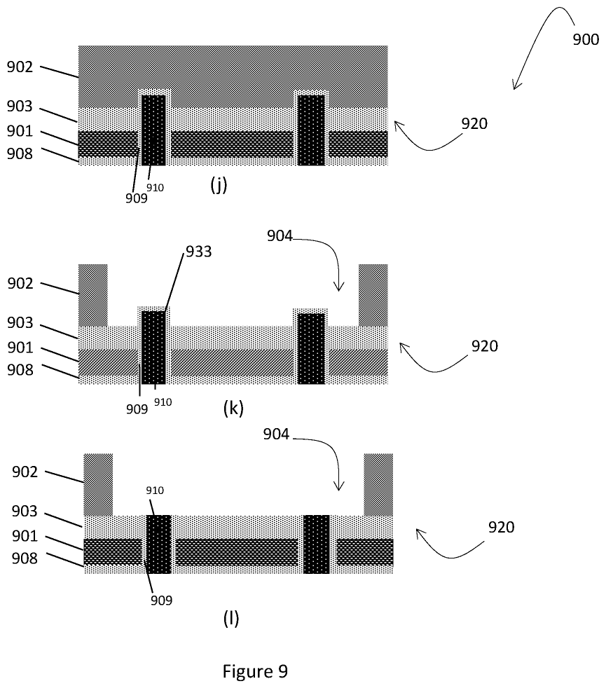

FIGS. 9(a)-9(l) illustrate another example process 900 for manufacturing an IC including an active substrate and a bulk substrate having a cavity, in accordance with various embodiments. In embodiments, various processes may be used to manufacture an IC, e.g., the IC 100 of FIG. 1, the IC 200 of FIG. 2, the IC 300 of FIG. 3, etc.

As shown in FIG. 9(a), an IC 920 may be provided. The IC 920 may include an active substrate 901, a bulk substrate 902, and a first oxide layer 903 between the active substrate 901 and the bulk substrate 902. The active substrate 901 may be similar to the active substrate 101, the bulk substrate 902 may be similar to the bulk substrate 102, while the first oxide layer 903 may be similar to the oxide layer 103 separating the active substrate 101 and the bulk substrate 102. The active substrate 901 may include devices or circuitry, not shown for simplicity reasons.

As shown in FIG. 9(b), a photoresist layer 951 may be formed on a surface of the active substrate 901. In embodiments, the photoresist layer 951 may be patterned to have a gap 952, which may be used to guide the location of a TSV to be formed.

As shown in FIG. 9(c), a gap 953 may be formed in the active substrate 901, following the pattern of the gap 952 in the photoresist layer 951. The gap 953 may stop at the first oxide layer 903.

As shown in FIG. 9(d), a gap 954 may be formed on the first oxide layer 903, following the pattern of the gap 952 in the photoresist layer 951. The gap 954 may be formed by using a chemical compound to etch through the first oxide layer 903. The chemical compound may be different from the chemical compound used in forming the gap 953 on the active substrate 901, due to the difference in materials in the first oxide layer 903 and the active substrate 901.

As shown in FIG. 9(e), a gap 955 may be further formed on the bulk substrate 902, following the pattern of the gap 952 in the photoresist layer 951. The gap 955 may be formed using a similar chemical compound as used in forming the gap 953 in the active substrate 901.

As shown in FIG. 9(f), the photoresist layer 951 may be stripped away. The gap 953, the gap 954, and the gap 955 may form an opening to be used to form a TSV through the active substrate 901, the first oxide layer 903, and partially into the bulk substrate 902.

As shown in FIG. 9(g), a second oxide layer 908 may be formed conformally with the surface of the active substrate 901. The second oxide layer 908 may also cover around the walls of the opening formed by the gap 953, the gap 954, and the gap 955, to form a vertical oxide layer 909.

As shown in FIG. 9(h), a metal layer 915 may be formed covering the second oxide layer 908 and the vertical oxide layer 909, filling the opening formed by the gap 953, the gap 954, and the gap 955. The metal layer 915 may include copper (Cu), or other conductive material, and may be formed by an electrochemical deposition (ECD) process.

As shown in FIG. 9(i), the metal layer 915 may be etched back and removed at the surface of the second oxide layer 908, while maintaining the part within the opening formed by the gap 953, the gap 954, and the gap 955. The part of the metal layer within the opening may form a TSV 910.

As shown in FIG. 9(j), the IC 920 may be flipped over so that the bulk substrate 902 may be on top for further processing. Before further processing is performed on the bulk substrate 902, photoresist may be deposited on the bulk substrate 902, which is not shown for simplicity reasons.

As shown in FIG. 9(k), a part of the bulk substrate 902 may be removed to form a cavity 904. The cavity 904 may be formed by etching the backside of the bulk substrate 902 to a desired size, e.g., thickness or width. For example, the bulk substrate 902 may be removed partially so that the cavity 904 includes the bulk substrate 902 as its bottom, so that the cavity 904 may be similar to the cavity 104 in FIG. 1. Alternatively, the bulk substrate 902 may be removed completely so that the cavity 904 does not include the bulk substrate 902 as its bottom. Instead, the cavity 904 may include the first oxide layer 903 as its bottom, so that the cavity 904 may be similar to the cavity 204 in FIG. 2. The first oxide layer 903 may function as a stop layer to stop from further etching when the desired etch depth is reached. The cavity 904 may expose a part of the vertical oxide layer 909 and the TSV 910, e.g., a component 933.

As shown in FIG. 9(l), the exposed part of the TSV 910 and the vertical oxide layer 909, e.g., the component 933, may be removed so that the cavity 904 may have a smooth bottom. The component 933 may be removed by anisotropic oxide etch, or other techniques. As demonstrated in FIG. 9(l), the cavity 904 may be similar to the cavity 104 of IC 100 in FIG. 1, or the cavity 204 of IC 200 in FIG. 2.

In embodiments, there may be more than one cavity formed following the process 900 shown in FIGS. 9(a)-9(l). Once the cavity 904 is formed, a chip to wafer bonding process may be applied to place a second IC into the cavity 904 of the IC 920. In some embodiments, a third IC may be placed on the second IC, which is not shown for simplicity reasons.

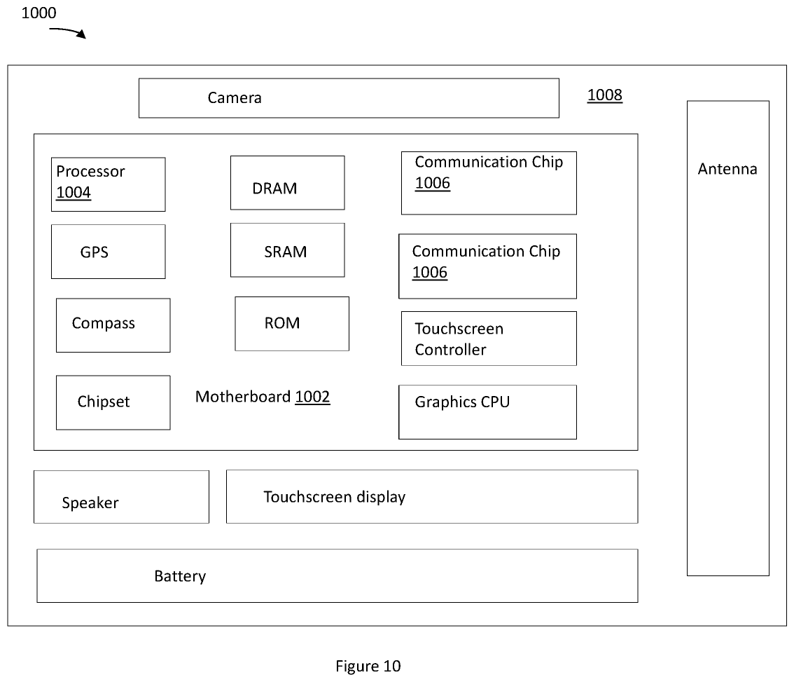

FIG. 10 illustrates an example system configured to employ the apparatuses and methods described herein, in accordance with various embodiments. FIG. 10 illustrates an example computing device 1000 that may employ the apparatuses and/or methods described herein (e.g., the IC 100, the IC 200, the IC 300, the stacking IC 400, the stacking IC 500, the stacking IC 600, and the stacking IC 700), in accordance with various embodiments.

Components of the computing device 1000 may be housed in an enclosure (e.g., housing 1008). The motherboard 1002 may include a number of components, including but not limited to a processor 1004 and at least one communication chip 1006. The processor 1004 may be physically and electrically coupled to the motherboard 1002. In some implementations, the at least one communication chip 1006 may also be physically and electrically coupled to the motherboard 1002. In further implementations, the communication chip 1006 may be part of the processor 1004.

Depending on its applications, computing device 1000 may include other components that may or may not be physically and electrically coupled to the motherboard 1002. These other components may include, but are not limited to, volatile memory, e.g., static random access memory (SRAM) or dynamic random access memory (DRAM), non-volatile memory (e.g., ROM), flash memory, a graphics central processing unit (CPU), a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

In embodiments, the processor 1004, the communication chip 1006, or the other components may be included in an IC, such as the IC 100, the IC 200, the IC 300. In embodiments, the processor 1004, the communication chip 1006, and other component may be coupled together in a stacking IC, such as the stacking IC 400, the stacking IC 500, the stacking IC 600, and the stacking IC 700.

The communication chip 1006 may enable wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wireless access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1006 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1006 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1006 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 1006 may operate in accordance with other wireless protocols in other embodiments.

The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, EV-DO, and others.

In various implementations, the computing device 1000 may be a mobile computing device, a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1000 may be any other electronic device that processes data.

Some non-limiting Examples are presented below.

Example 1 may include a stacking integrated circuit (IC), comprising: an IC, wherein the IC includes: an active substrate, wherein the active substrate includes a device; an oxide layer on one side of the active substrate; a bulk substrate on the oxide layer, wherein the bulk substrate includes a cavity surrounded by a first edge of the bulk substrate and a second edge of the bulk substrate; and a through silicon via (TSV) through the active substrate, wherein the TSV is exposed in the cavity of the bulk substrate, the TSV is separated from the active substrate by a vertical oxide layer through the active substrate, and the vertical oxide layer is in contact with the oxide layer.

Example 2 may include the stacking IC of example 1 and/or some other examples herein, wherein the cavity of the bulk substrate is completely through the bulk substrate, and surrounded by the first edge of the bulk substrate, the second edge of the bulk substrate, and the oxide layer.

Example 3 may include the stacking IC of example 1 and/or some other examples herein, wherein the IC further includes: another oxide layer on another side of the active substrate, wherein the another side is opposite to the one side, and the another oxide layer is in contact with the vertical oxide layer.

Example 4 may include the stacking IC of example 1 and/or some other examples herein, wherein the IC includes a die or a wafer.

Example 5 may include the stacking IC of example 1 and/or some other examples herein, further including: a second IC placed within the cavity of the bulk substrate, wherein the second IC includes a die, and a connector connected to the TSV.

Example 6 may include the stacking IC of example 5 and/or some other examples herein, wherein the second IC includes: a second active substrate, wherein the second active substrate includes a second device; a second oxide layer on the second active substrate; a second bulk substrate on the second oxide layer, wherein the second bulk substrate includes a cavity surrounded by a first edge of the second bulk substrate and a second edge of the second bulk substrate; and a second TSV through the second active substrate, wherein the second TSV is exposed in the cavity of the second bulk substrate.

Example 7 may include the stacking IC of example 6 and/or some other examples herein, further including: a third IC placed within the cavity of the second bulk substrate, wherein the third IC includes a die, and a connector connected to the second TSV.

Example 8 may include the stacking IC of example 1 and/or some other examples herein, wherein the IC includes a wafer, and the bulk substrate further includes a second cavity of the bulk substrate formed by the second edge of the bulk substrate, and a third edge of the bulk substrate.

Example 9 may include the stacking IC of example 8 and/or some other examples herein, further including: a fourth IC placed within the second cavity of the bulk substrate.

Example 10 may include the stacking IC of any of examples 1-9 and/or some other examples herein, wherein the TSV includes copper (Cu), tungsten (W), polysilicon, doped silicon, or gold (Au).

Example 11 may include the stacking IC of any of examples 1-9 and/or some other examples herein, wherein the active substrate or the bulk substrate includes a polymeric substrate, a non-polymeric substrate, a silicon substrate, a silicon on insulator (SOI) substrate, or a silicon on sapphire (SOS) substrate.

Example 12 may include the stacking IC of any of examples 1-9 and/or some other examples herein, wherein the oxide layer includes a silicon dioxide (SiO₂), or a silicon oxide.

Example 13 may include a method for making a stacking integrated circuit (IC), comprising: providing an IC, wherein the IC includes an active substrate, a bulk substrate, and a first oxide layer between the active substrate and the bulk substrate; forming an opening through the active substrate, the first oxide layer, and partially into the bulk substrate; forming a second oxide layer conformal to a surface of the active substrate, and around walls of the opening; forming a through silicon via (TSV) next to the second oxide layer in the opening to fill the opening; and forming a cavity of the bulk substrate by removing a part of the bulk substrate, wherein the TSV is exposed in the cavity of the bulk substrate, and wherein the cavity of the bulk substrate is surrounded by a first edge of the bulk substrate and a second edge of the bulk substrate.

Example 14 may include the method of example 13 and/or some other examples herein, wherein the IC includes a die or a wafer.

Example 15 may include the method of example 13 and/or some other examples herein, further including: placing a second IC within the cavity of the bulk substrate, wherein the second IC includes a die, and a connector to connect to the TSV.

Example 16 may include the method of any of examples 13-15 and/or some other examples herein, wherein the IC includes a wafer, the cavity of the bulk substrate is a first cavity, and the method further including: forming a second cavity of the bulk substrate by removing a second part of the bulk substrate, wherein the second cavity of the bulk substrate is surrounded by the second edge of the bulk substrate and a third edge of the bulk substrate.

Example 17 may include the method of any of examples 13-15 and/or some other examples herein, further including: placing a third IC within the second cavity of the bulk substrate.

Example 18 may include an electronic system, comprising: a printed circuit board (PCB); and a stacking integrated circuit (IC) affixed to the PCB, wherein the stacking IC includes: a first IC, wherein the first IC includes: an active substrate, wherein the active substrate includes a device; an oxide layer on the active substrate; a bulk substrate on the oxide layer, wherein the bulk substrate includes a cavity surrounded by a first edge of the bulk substrate and a second edge of the bulk substrate; and a through silicon via (TSV) through the active substrate, wherein the TSV is exposed in the cavity of the bulk substrate, the TSV is separated from the active substrate by a vertical oxide layer through the active substrate, and the vertical oxide layer is in contact with the oxide layer; and a second IC placed within the cavity of the bulk substrate, wherein the second IC includes a die, and a connector connected to the TSV.

Example 19 may include the electronic system of example 18 and/or some other examples herein, wherein the cavity of the bulk substrate is completely through the bulk substrate, and surrounded by the first edge of the bulk substrate, the second edge of the bulk substrate, and the oxide layer.

Example 20 may include the electronic system of example 18 and/or some other examples herein, wherein the first IC includes a die or a wafer.

Example 21 may include the electronic system of example 18 and/or some other examples herein, wherein the second IC includes: a second active substrate, wherein the second active substrate includes a second device; a second oxide layer on the second active substrate; a second bulk substrate on the second oxide layer, wherein the second bulk substrate includes a cavity surrounded by a first edge of the second bulk substrate and a second edge of the second bulk substrate; and a second TSV through the second active substrate, wherein the second TSV is exposed in the cavity of the second bulk substrate; and the electronic system further includes: a third IC placed within the cavity of the second bulk substrate, wherein the third IC includes a die, and a connector connected to the second TSV.

Example 22 may include the electronic system of example 18 and/or some other examples herein, wherein the first IC includes a wafer, and the bulk substrate further includes a second cavity of the bulk substrate formed by the second edge of the bulk substrate, and a third edge of the bulk substrate, and the electronic system further includes: a fourth IC placed within the second cavity of the bulk substrate.

Example 23 may include the electronic system of any of examples 18-22 and/or some other examples herein, wherein the TSV includes copper (Cu), tungsten (W), polysilicon, doped silicon, or gold (Au).

Example 24 may include the electronic system of any of examples 18-22 and/or some other examples herein, wherein the active substrate or the bulk substrate includes a polymeric substrate, a non-polymeric substrate, a silicon substrate, a silicon on insulator (SOI) substrate, or a silicon on sapphire (SOS) substrate.

Example 25 may include the electronic system of any of examples 18-22 and/or some other examples herein, wherein the oxide layer includes a silicon dioxide (SiO2), or a silicon oxide.

Although certain embodiments have been illustrated and described herein for purpose of description, this application is intended to cover any adaptations or variations of the embodiments discussed herein. Therefore, it is manifestly intended that embodiments described herein be limited only by the claims.

1-25. (canceled)

26. A stacking integrated circuit (IC), comprising:
an IC, wherein the IC includes:
an active substrate, wherein the active substrate includes a device;
an oxide layer on one side of the active substrate;
a bulk substrate on the oxide layer, wherein the bulk substrate includes a cavity surrounded by a first edge of the bulk substrate and a second edge of the bulk substrate; and
a through silicon via (TSV) through the active substrate, wherein the TSV is exposed in the cavity of the bulk substrate, the TSV is separated from the active substrate by a vertical oxide layer through the active substrate, and the vertical oxide layer is in contact with the oxide layer.

27. The stacking IC of claim 26, wherein the cavity of the bulk substrate is completely through the bulk substrate, and surrounded by the first edge of the bulk substrate, the second edge of the bulk substrate, and the oxide layer.

28. The stacking IC of claim 26, wherein the IC further includes:
another oxide layer on another side of the active substrate, wherein the another side is opposite to the one side, and the another oxide layer is in contact with the vertical oxide layer.

29. The stacking IC of claim 26, wherein the IC includes a die or a wafer.

30. The stacking IC of claim 26, further including:
a second IC placed within the cavity of the bulk substrate, wherein the second IC includes a die, and a connector connected to the TSV.

31. The stacking IC of claim 30, wherein the second IC includes:
a second active substrate, wherein the second active substrate includes a second device;
a second oxide layer on the second active substrate;
a second bulk substrate on the second oxide layer, wherein the second bulk substrate includes a cavity surrounded by a first edge of the second bulk substrate and a second edge of the second bulk substrate; and
a second TSV through the second active substrate, wherein the second TSV is exposed in the cavity of the second bulk substrate.

32. The stacking IC of claim 31, further including:
a third IC placed within the cavity of the second bulk substrate, wherein the third IC includes a die, and a connector connected to the second TSV.

33. The stacking IC of claim 26, wherein the IC includes a wafer, and the bulk substrate further includes a second cavity of the bulk substrate formed by the second edge of the bulk substrate, and a third edge of the bulk substrate.

34. The stacking IC of claim 33, further including:
a fourth IC placed within the second cavity of the bulk substrate.

35. The stacking IC of claim 26, wherein the TSV includes copper (Cu), tungsten (W), polysilicon, doped silicon, or gold (Au).

36. The stacking IC of claim 26, wherein the active substrate or the bulk substrate includes a polymeric substrate, a non-polymeric substrate, a silicon substrate, a silicon on insulator (SOI) substrate, or a silicon on sapphire (SOS) substrate.

37. The stacking IC of claim 26, wherein the oxide layer includes a silicon dioxide (SiO₂), or a silicon oxide.

38. A method for making a stacking integrated circuit (IC), comprising:
providing an IC, wherein the IC includes an active substrate, a bulk substrate, and a first oxide layer between the active substrate and the bulk substrate;
forming an opening through the active substrate, the first oxide layer, and partially into the bulk substrate;
forming a second oxide layer conformal to a surface of the active substrate, and around walls of the opening;
forming a through silicon via (TSV) next to the second oxide layer in the opening to fill the opening; and
forming a cavity of the bulk substrate by removing a part of the bulk substrate, wherein the TSV is exposed in the cavity of the bulk substrate, and wherein the cavity of the bulk substrate is surrounded by a first edge of the bulk substrate and a second edge of the bulk substrate.

39. The method of claim 38, wherein the IC includes a die or a wafer.

40. The method of claim 38, further including:
placing a second IC within the cavity of the bulk substrate, wherein the second IC includes a die, and a connector to connect to the TSV.

41. The method of claim 38, wherein the IC includes a wafer, the cavity of the bulk substrate is a first cavity, and the method further including:
forming a second cavity of the bulk substrate by removing a second part of the bulk substrate, wherein the second cavity of the bulk substrate is surrounded by the second edge of the bulk substrate and a third edge of the bulk substrate.

42. The method of claim 41, further including:
placing a third IC within the second cavity of the bulk substrate.

43. An electronic system, comprising:
a printed circuit board (PCB); and
a stacking integrated circuit (IC) affixed to the PCB, wherein the stacking IC includes:
a first IC, wherein the first IC includes:
an active substrate, wherein the active substrate includes a device;
an oxide layer on the active substrate;
a bulk substrate on the oxide layer, wherein the bulk substrate includes a cavity surrounded by a first edge of the bulk substrate and a second edge of the bulk substrate; and
a through silicon via (TSV) through the active substrate, wherein the TSV is exposed in the cavity of the bulk substrate, the TSV is separated from the active substrate by a vertical oxide layer through the active substrate, and the vertical oxide layer is in contact with the oxide layer; and
a second IC placed within the cavity of the bulk substrate, wherein the second IC includes a die, and a connector connected to the TSV.

44. The electronic system of claim 43, wherein the cavity of the bulk substrate is completely through the bulk substrate, and surrounded by the first edge of the bulk substrate, the second edge of the bulk substrate, and the oxide layer.

45. The electronic system of claim 43, wherein the first IC includes a die or a wafer.

46. The electronic system of claim 43, wherein the second IC includes:
a second active substrate, wherein the second active substrate includes a second device;
a second oxide layer on the second active substrate;
a second bulk substrate on the second oxide layer, wherein the second bulk substrate includes a cavity surrounded by a first edge of the second bulk substrate and a second edge of the second bulk substrate; and
a second TSV through the second active substrate, wherein the second TSV is exposed in the cavity of the second bulk substrate; and
the electronic system further includes:
a third IC placed within the cavity of the second bulk substrate, wherein the third IC includes a die, and a connector connected to the second TSV.

47. The electronic system of claim 43, wherein the first IC includes a wafer, and the bulk substrate further includes a second cavity of the bulk substrate formed by the second edge of the bulk substrate, and a third edge of the bulk substrate, and
the electronic system further includes:
a fourth IC placed within the second cavity of the bulk substrate.

48. The electronic system of claim 43, wherein the TSV includes copper (Cu), tungsten (W), polysilicon, doped silicon, or gold (Au).

49. The electronic system of claim 43, wherein the active substrate or the bulk substrate includes a polymeric substrate, a non-polymeric substrate, a silicon substrate, a silicon on insulator (SOI) substrate, or a silicon on sapphire (SOS) substrate.

50. The electronic system of claim 43, wherein the oxide layer includes a silicon dioxide (SiO2), or a silicon oxide.
